(19) United States
(12) Patent Application Publication
(10) Pub. No.: US 2015/0179959 A1
(43) Pub. Date: Jun. 25, 2015

(54) ORGANIC METAL COMPOUND, ORGANIC LIGHT-EMITTING DEVICE EMPLOYING THE SAME, AND METHOD FOR PREPARING THE SAME

(71) Applicants: INDUSTRIAL TECHNOLOGY RESEARCH INSTITUTE, Hsinchu (TW); RITDISPLAY CORPORATION, Hukou Township (TW)

(72) Inventors: Jin-Sheng LIN, Taipei City (TW); Jia-Lun LIOU, Hengshan Township (TW); Chun-Neng KU, Tainan City (TW); Meng-Hao CHANG, New Taipei City (TW); Han-Cheng YEH, Taipei City (TW)

(73) Assignees: RITDISPLAY CORPORATION, Hukou Township (TW); INDUSTRIAL TECHNOLOGY RESEARCH INSTITUTE, Hsinchu (TW)

(21) Appl. No.: 14/565,549

(22) Filed: Dec. 10, 2014

(30) Foreign Application Priority Data
Dec. 25, 2013 (TW) 102148206

(51) Int. Cl. H01L 51/00; H01L 51/50

(52) U.S. Cl. CPC H01L 51/0085; H01L 51/5012

(57) ABSTRACT

Organic metal compounds, organic light-emitting devices, and a method for preparing the same are provided. The organic metal compound has a chemical structure represented by Formula (I):

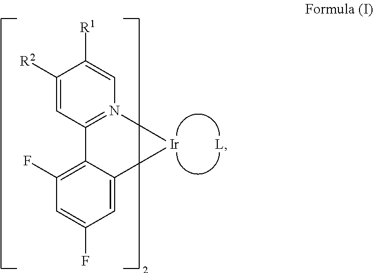

wherein one of R¹ and R² is hydrogen, and the other is trialkyl silyl group; and L is an acetylacetone ligand, a picolinate ligand, a 2-(imidazol-2-yl) pyridine ligand, a 2-(4,5-dimethyl-imidazol-2-yl)pyridine ligand, a 3-(trifluoromethyl)-5-(pyridine-2-yl)-1,2,4-triazolate ligand, or a 3-(tert-butyl)-5-(pyridine-2-yl)-1,2,4-triazolate ligand.

### CROSS REFERENCE TO RELATED APPLICATIONS

This application is based upon and claims the benefit of priority from the prior Taiwan Patent Application No. 102148206, filed on 25 Dec. 2013, the entire contents of which are incorporated herein by reference.

### TECHNICAL FIELD

The disclosure relates to an organic metal compound, organic light-emitting device, and method for preparing the same.

### BACKGROUND

Recently, with the development and wide application of electronic products, such as mobile phones, PDAs, and notebook computers, there has been increasing demand for flat display elements which consume less electric power and occupy less space. Organic light-emitting devices (OLED) are self-emitting and highly luminous, with wide viewing angles, fast response speeds, and simple fabrication methods, making them an industry display of choice.

Generally, an organic light-emitting device is composed of a light-emission layer sandwiched between a pair of electrodes. When an electric field is applied to the electrodes, the cathode injects electrons into the light-emission layer and the anode injects holes into the light-emission layer. When the electrons recombine with the holes in the light-emission layer, excitons are formed. Recombination of the electron and hole results in light emission.

Depending on the spin states of the hole and electron, the exciton, which results from the recombination of the hole and electron, can have either a triplet or singlet spin state. Luminescence from a singlet exciton results in fluorescence whereas luminescence from a triplet exciton results in phosphorescence. The emissive efficiency of phosphorescence is three times that of fluorescence.

Therefore, it is crucial to develop highly efficient phosphorescent material, in order to increase the emissive efficiency of an OLED.

### SUMMARY

According to an embodiment of the disclosure, the disclosure provides an organic metal compound having Formula (I):

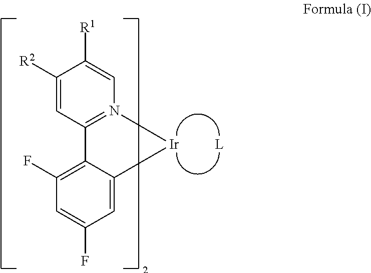

wherein, one of R¹ and R² is hydrogen, and the other one is trialkyl silyl group; and L is acetylacetone ligand, picolinate ligand, 2-(imidazol-2-yl) pyridine ligand, dimethyl-imidazol-2-yl)pyridine ligand, 3-(trifluoromethyl)-5-(pyridine-2-yl)-1,2,4-triazolate ligand, or 3-(tert-butyl)-5-(pyridine-2-yl)-1,2,4-triazolate ligand.

According to another embodiment of the disclosure, the disclosure also provides an organic light-emitting device, which includes a pair of electrodes; and an organic light-emitting element disposed between the electrodes, wherein the organic light-emitting element includes the aforementioned organic metal compound.

According to embodiments of the disclosure, the disclosure provides a method for preparing the aforementioned organic metal compound. The method includes reacting a compound having a structure of Formula (II) with acetyl acetone, picolinic acid, 2-(1H-imidazol-2-yl)pyridine, 2-(4,5-dimethyl-1H-imidazol-2-yl)pyridine, 2-[3-(trifluoromethyl)-1H-1,2,4-triazol-5-yl]pyridine, or 2-[3-(tert-butyl)-1H-1,2,4-triazol-5-yl]pyridine, in the presence of triethylamine, obtaining an organic metal compound having Formula (I):

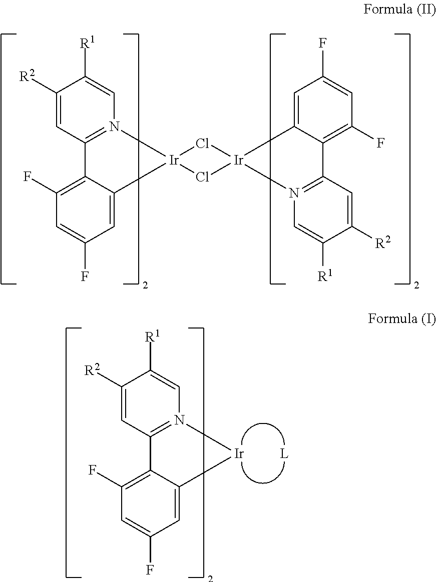

wherein, one of R¹ and R² is hydrogen, and the other one is trialkyl silyl group; and L is acetylacetone ligand, picolinate ligand, 2-(imidazol-2-yl) pyridine ligand, dimethyl-imidazol-2-yl)pyridine ligand, 3-(trifluoromethyl)-5-(pyridine-2-yl)-1,2,4-triazolate ligand, or 3-(tert-butyl)-5-(pyridine-2-yl)-1,2,4-triazolate ligand.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 shows photoluminescence (PL) spectra of the organic metal compounds (I)-(III) and (V) of the disclosure.

FIG. 2 shows a cross section of an organic light-emitting device disclosed by an embodiment of the disclosure.

### DETAILED DESCRIPTION

The following description is of the best-contemplated mode of carrying out the disclosure. This description is made for the purpose of illustrating the general principles of the disclosure and should not be taken in a limiting sense. The scope of the disclosure is best determined by reference to the appended claims.

Organic Metal Compound

According to embodiments of the disclosure, the disclosure provides an organic metal compound having Formula (I):

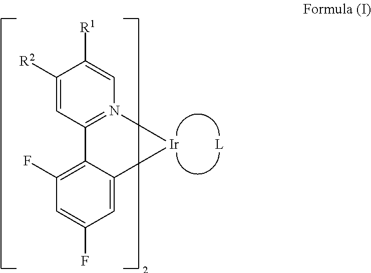

wherein, one of R¹ and R² can be hydrogen, and the other one can be trialkyl silyl group; and L is acetylacetone ligand, picolinate ligand, 2-(imidazol-2-yl) pyridine ligand, 2-(4,5-dimethyl-imidazol-2-yl)pyridine ligand, 3-(trifluoromethyl)-5-(pyridine-2-yl)-1,2,4-triazolate ligand, or 3-(tert-butyl)-5-(pyridine-2-yl)-1,2,4-triazolate ligand. Herein, the acetylacetone ligand can be a non-substituted acetylacetone ligand, or a substituted acetylacetone ligand, such as

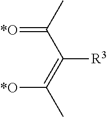

(atoms marked by * are bonded with Ir), wherein R³ can be hydrogen, C₁₋₁₀ alkyl group, C₅₋₁₀ cycloalkyl group, or C₅₋₁₂ aromatic group; the picolinate ligand can be a non-substituted picolinate ligand, or a substituted picolinate ligand, such as

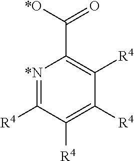

(atoms marked by * are bonded with Ir), wherein each R⁴ can be independently hydrogen, C₁₋₁₀ alkyl group, C₅₋₁₀ cycloalkyl group, or C₅₋₁₂ aromatic group; the 2-(imidazol-2-yl) pyridineligand can be a non-substituted 2-(imidazol-2-yl) pyridineligand, or a substituted 2-(imidazol-2-yl) pyridineligand, such as

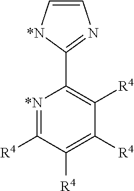

(atoms marked by * are bonded with Ir), wherein each R⁴ can be independently hydrogen, C₁₋₁₀ alkyl group, C₅₋₁₀ cycloalkyl group, or C₅₋₁₂ aromatic group; the 2-(4,5-dimethyl-imidazol-2-yl)pyridine ligand can be a non-substituted 2-(4,5-dimethyl-imidazol-2-yl)pyridine ligand, or a substituted 2-(4,5-dimethyl-imidazol-2-yl)pyridine ligand, such as

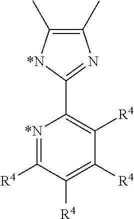

(atoms marked by * are bonded with Ir), wherein each R⁴ can be independently hydrogen, C₁₋₁₀ alkyl group, C₅₋₁₀ cycloalkyl group, or C₅₋₁₂ aromatic group; the 3-(trifluoromethyl)-5-(pyridine-2-yl)-1,2,4-triazolate ligand can be a non-substituted 3-(trifluoromethyl)-5-(pyridine-2-yl)-1,2,4-triazolate ligand, or a substituted 3-(trifluoromethyl)-5-(pyridine-2-yl)-1,2,4-triazolate ligand, such as

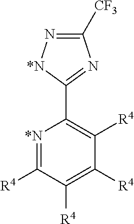

(atoms marked by * are bonded with Ir), wherein each R⁴ can be independently hydrogen, C₁₋₁₀ alkyl group, C₅₋₁₀ cycloalkyl group, or C₅₋₁₂ aromatic group; and, the 3-(tert-butyl)-5-(pyridine-2-yl)-1,2,4-triazolate ligand can be a non-substituted 3-(tert-butyl)-5-(pyridine-2-yl)-1,2,4-triazolate ligand, or a substituted 3-(tert-butyl)-5-(pyridine-2-yl)-1,2,4-triazolate ligand, such as

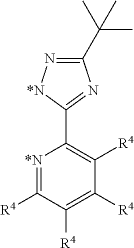

(atoms marked by * are bonded with Ir), wherein each R⁴ can be independently hydrogen, C₁₋₁₀ alkyl group, C₅₋₁₀ cycloalkyl group, or C₅₋₁₂ aromatic group.

The organic metal compounds of the disclosure can serve as a phosphorescent dopant material (having a maximum luminous intensity peak of between about 400 nm to 530 nm), and can be applied to an organic light-emitting device for enhancing the luminous efficiency.

According to embodiments of the disclosure, R¹ can be hydrogen, and R² can be trimethylsilyl group, triethylsilyl group, triphenylsilyl group, tripropylsilyl group, butyldimethylsilyl group, propyldimethylsilyl group, vinyldimethylsilyl group, or t-butyldimethylsilyl group. In addition, R² can be hydrogen, and R¹ can be trimethylsilyl group, triethylsilyl group, triphenylsilyl group, tripropylsilyl group, butyldimethylsilyl group, propyldimethylsilyl group, vinyldimethylsilyl group, or t-butyldimethylsilyl group.

According to some embodiments of the disclosure, the organic metal compound can be:

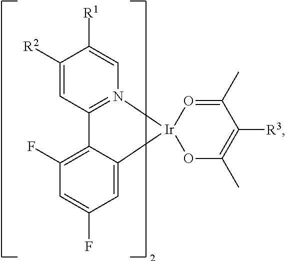

wherein one of R¹ and R² is hydrogen, and the other one is trialkyl silyl group; and, R³ is hydrogen, C₁₋₁₀ alkyl group, C₅₋₁₀ cycloalkyl group, or C₅₋₁₂ aromatic group. for example, R¹ can be hydrogen, and R² can be trimethylsilyl group, triethylsilyl group, triphenylsilyl group, tripropylsilyl group, butyldimethylsilyl group, propyldimethylsilyl group, vinyldimethylsilyl group, or t-butyldimethylsilyl group. On the other hand, R² can be hydrogen, and R¹ can be trimethylsilyl group, triethylsilyl group, triphenylsilyl group, tripropylsilyl group, butyldimethylsilyl group, propyldimethylsilyl group, vinyldimethylsilyl group, or t-butyldimethylsilyl group. In addition, R³ can be hydrogen, methyl, ethyl, propyl, isopropyl, butyl, isobutyl, tert-butyl, pentyl, hexyl, cyclohexyl, phenyl, biphenyl, or naphthyl.

According to other embodiments of the disclosure, the organic metal compound can be

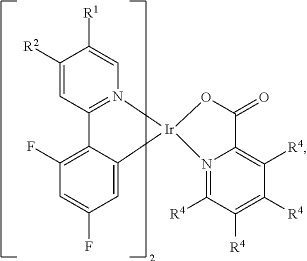

wherein one of R¹ and R² is hydrogen, and the other one is trialkyl silyl group; and, each R⁴ is independently hydrogen, C₁₋₁₀ alkyl group, C₅₋₁₀ cycloalkyl group, or C₅₋₁₂ aromatic group. For example, R¹ can be hydrogen, and R² can be trimethylsilyl group, triethylsilyl group, triphenylsilyl group, tripropylsilyl group, butyldimethylsilyl group, propyldimethylsilyl group, vinyldimethylsilyl group, or t-butyldimethylsilyl group. On the other hand, R² can be hydrogen, and R¹ can be trimethylsilyl group, triethylsilyl group, triphenylsilyl group, tripropylsilyl group, butyldimethylsilyl group, propyldimethylsilyl group, vinyldimethylsilyl group, or t-butyldimethylsilyl group. Further, each R⁴ can be independently hydrogen, methyl, ethyl, propyl, isopropyl, butyl, isobutyl, tert-butyl, pentyl, hexyl, cyclohexyl, phenyl, biphenyl, or naphthyl.

According to other embodiments of the disclosure, the organic metal compound can be

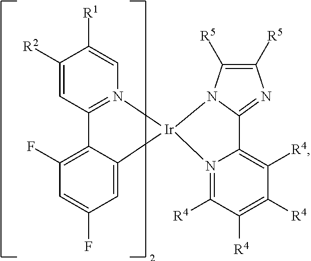

wherein one of R¹ and R² is hydrogen, and the other one is trialkyl silyl group; each R⁴ is independently hydrogen, C₁₋₁₀ alkyl group, C₅₋₁₀ cycloalkyl group, or C₅₋₁₂ aromatic group; and, R⁵ is hydrogen, or methyl group. For example, R¹ can be hydrogen, and R² can be trimethylsilyl group, triethylsilyl group, triphenylsilyl group, tripropylsilyl group, butyldimethylsilyl group, propyldimethylsilyl group, vinyldimethylsilyl group, or t-butyldimethylsilyl group. On the other hand, R² can be hydrogen, and R¹ can be trimethylsilyl group, triethylsilyl group, triphenylsilyl group, tripropylsilyl group, butyldimethylsilyl group, propyldimethylsilyl group, vinyldimethylsilyl group, or t-butyldimethylsilyl group. Further, each R⁴ can be independently hydrogen, methyl, ethyl, propyl, isopropyl, butyl, isobutyl, tert-butyl, pentyl, hexyl, cyclohexyl, phenyl, biphenyl, or naphthyl.

According to other embodiments of the disclosure, the organic metal compound can be

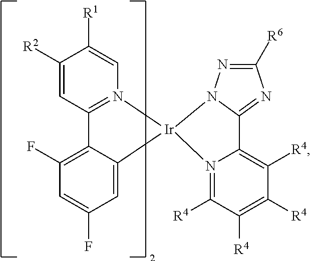

wherein one of R¹ and R² is hydrogen, and the other one is trialkyl silyl group; each R⁴ is independently hydrogen, C₁₋₁₀ alkyl group, C₅₋₁₀ cycloalkyl group, or C₅₋₁₂ aromatic group; and, R⁶ is fluoroalkyl group, or tert-butyl group. For example, R¹ can be hydrogen, and R² can be trimethylsilyl group, triethylsilyl group, triphenylsilyl group, tripropylsilyl group, butyldimethylsilyl group, propyldimethylsilyl group, vinyldimethylsilyl group, or t-butyldimethylsilyl group. On the other hand, R² can be hydrogen, and R¹ can be trimethylsilyl group, triethylsilyl group, triphenylsilyl group, tripropylsilyl group, butyldimethylsilyl group, propyldimethylsilyl group, vinyldimethylsilyl group, or t-butyldimethylsilyl group. Further, each R⁴ can be independently hydrogen, methyl, ethyl, propyl, isopropyl, butyl, isobutyl, tert-butyl, pentyl, hexyl, cyclohexyl, phenyl, biphenyl, or naphthyl.

Since the organic metal compound having Formula (I) of the disclosure has a trialkyl silyl group bonded on the pyridyl group of the ligand bonded with Ir, the organic metal compound having Formula (I) has an improved thermal-stability. Therefore, the organic metal compound having Formula (I) of the disclosure is suitable for being purified by a sublimation process (the organic metal compound having Formula (I) of the disclosure has a sublimation yield larger than 90%).

In addition, the organic metal compound having Formula (I) of the disclosure, which has a suitable highest occupied molecular orbital (HOMO) and lowest unoccupied molecular orbital (LUMO) energy gap (between 6.0 eV and 3.0 eV), facilitates the electrons recombining with the holes to form excitons, results in luminescence. Therefore, the organic metal compound having Formula (I) of the disclosure can serve as phosphorescence light-emitting material for enhancing the luminous efficiency of the organic light-emitting device employing the same.

In addition, the disclosure also provides a method for preparing the organic metal compound. The method includes the following steps: reacting a compound having a structure of Formula (II) with acetyl acetone, picolinic acid, 2-(1H-imidazol-2-yl)pyridine, 2-(4,5-dimethyl-1H-imidazol-2-yl)pyridine, 2-[3-(trifluoromethyl)-1H-1,2,4-triazol-5-yl]pyridine, or 2-[3-(tert-butyl)-1H-1,2,4-triazol-5-yl]pyridine, in the presence of triethylamine, obtaining an organic metal compound having Formula (I)

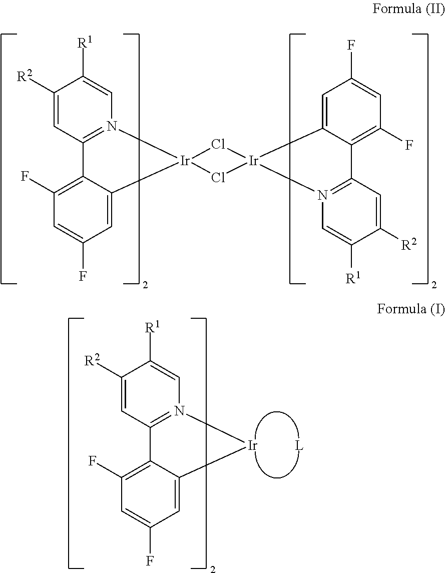

wherein, one of R¹ and R² is hydrogen, and the other one is trialkyl silyl group; and, L is acetylacetone ligand, picolinate ligand, 2-(imidazol-2-yl) pyridine ligand, dimethyl-imidazol-2-yl)pyridine ligand, 3-(trifluoromethyl)-5-(pyridine-2-yl)-1,2,4-triazolate ligand, or 3-(tert-butyl)-5-(pyridine-2-yl)-1,2,4-triazolate ligand.

According to embodiments of the disclosure, the organic metal compound having Formula (I) of the disclosure can be

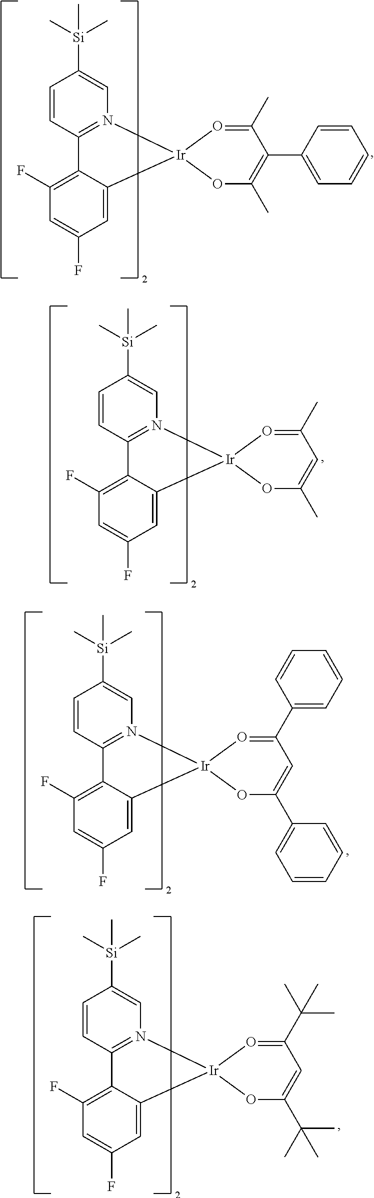

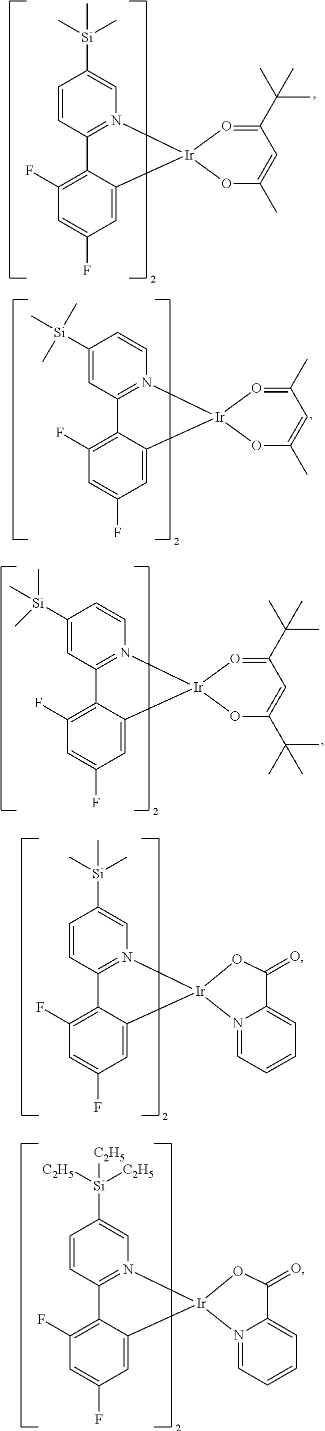

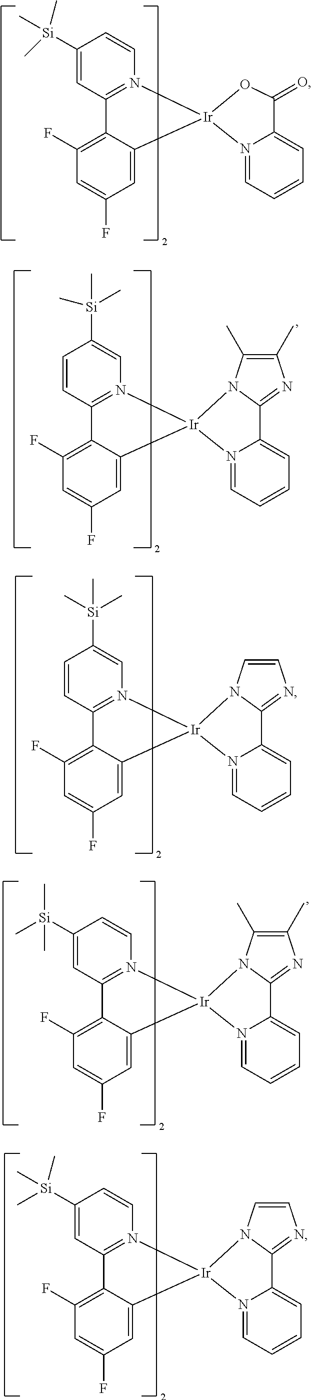

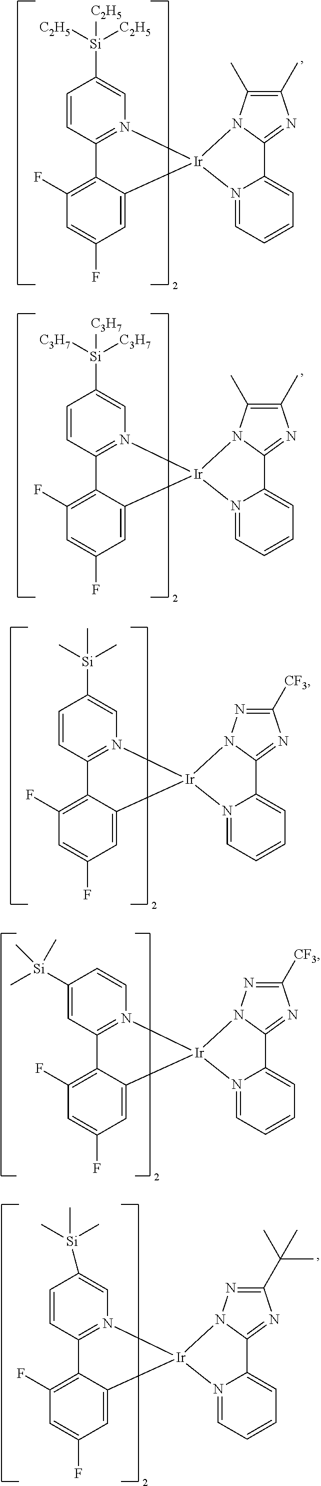

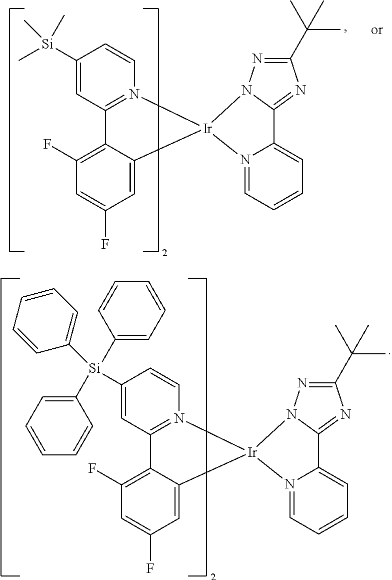

The following examples are intended to illustrate the disclosure more fully without limiting the scope, since numerous modifications and variations will be apparent to those skilled in this art.

### Example 1

### Preparation of Organic Metal Compound (I)

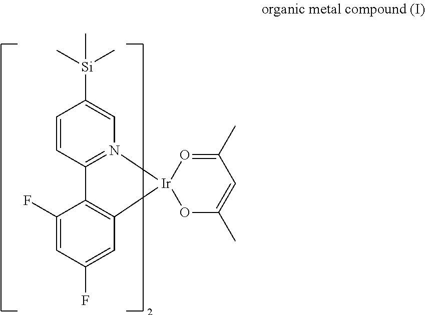

1 g (4.22 mmol) of 2,5-dibromopyridine and 40 mL of ether were added into a 100 mL reaction bottle after removing moisture and purging nitrogen gas several times. After cooling to −78° C., n-BuLi (3 mL (4.64 mmol)) was slowly added into the reaction bottle. After stirring for 1 hr, 0.65 mL (5 mmol) of trimethylchlorosilane (TMSCl) was added into the reaction bottle. After returning to room temperature, the result was extracted three times using ethyl acetate (EA) and water as the extraction solvent. An organic phase was separated and dried, and then purified by column chromatography, obtaining compound (1) with a yield larger than 80%. The synthesis pathway of the above reaction was as follows:

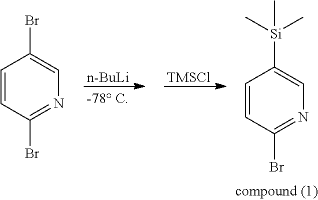

The physical measurement of the compound (1) is listed below: ¹H NMR (200 MHz, CDCl₃, 294 K): δ 8.40 (s, 1H), 7.61 (d, 1H), 7.45 (d, 1H), 0.29 (s, 9H).

0.7 g (3 mmol) of compound (1), 0.52 g (3.3 mmol) of 2,4-difluorophenyl bronic acid, and 0.4 g (1 mmol) of potassium carbonate were added into a reaction bottle. Next, 20 mL of dimethoxyethane, 40 mL of water, and a catalyst amount of tetrakis(triphenylphosphine)palladium (Pd(PPh₃)₄) were added into the reaction bottle. After removing moisture and purging nitrogen gas several times, the mixture was heated to reflux. After reacting for 8 hr and then cooling to room temperature, NaHCO₃ (aq) was added into the reaction bottle to adjust the pH value to a weak base condition. Next, the result was extracted three times using ethyl acetate (EA) and water as the extraction solvent. Next, an organic phase was separated and dried, and then purified by column chromatography, obtaining compound (2) with a yield larger than 80%. The synthesis pathway of the above reaction was as follows:

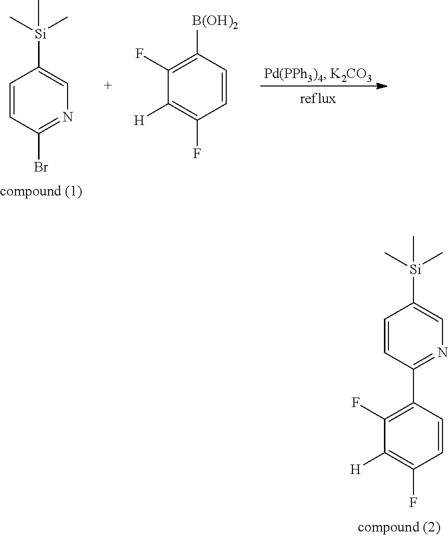 [SMILES: C[Si](C)(C)c1ccc(Br)nc1 ; OB(O)c1ccc(F)cc1F ; C[Si](C)(C)c1ccc(-c2ccc(F)cc2F)nc1]

The physical measurement of the compound (2) is listed below: ¹H NMR (200 MHz, CDCl₃, 294 K): δ 8.77 (s, 1H), 7.98 (q, 1H), 7.86 (d, 1H), 7.70 (d, 1H), 7.04-6.85 (m, 2H), 0.33 (s, 9H). Elemental analysis: C₁₄H₁₅F₂NSi: N, 5.32; C, 63.85; H, 5.74. Found: N, 5.30; C, 63.78; H, 5.73.

Next, 1.7 g (6.6 mmol) of compound (2), and 0.89 g (3 mmol) of IrCl₃ were added into a reaction bottle. Next, 24 mL of dimethoxyethane and 8 mL of water were added into the reaction bottle. After removing moisture and purging nitrogen gas several times, the mixture was heated to 120° C. After reacting for 8 hr, the result was filtrated and the filter cake was collected and washed with water and hexane, and then dried under vacuum, obtaining compound (3). The synthesis pathway of the above reaction was as follows:

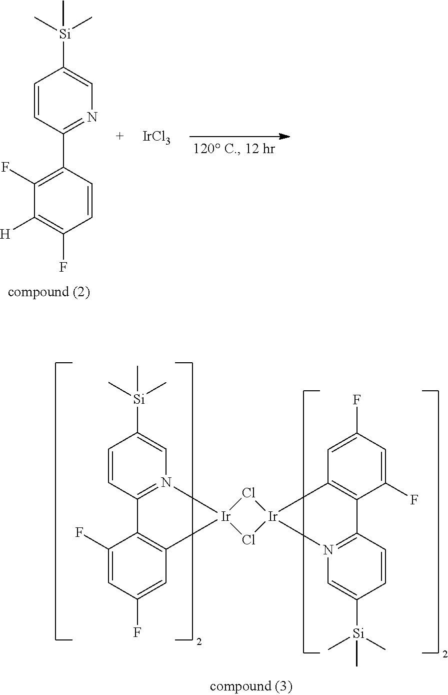

The physical measurement of the compound (3) is listed below: ¹H NMR (200 MHz, CDCl₃, 294 K): δ 9.51 (s, 2H), 9.28 (s, 2H), 8.22 (d, 2H), 7.94 (d, 2H), 7.80 (d, 2H), 7.67 (d, 2H), 6.41-6.27 (m, 4H), 5.43 (d, 2H), 5.03 (d, 2H), 0.13 (s, 18H), 0.05 (s, 18H).

Next, 0.5 g (0.33 mmol) of compound (3), 133 mg (1.33 mmol) of acetyl acetone, and 0.1 ml (1.33 mmol) of triethylamine (Et₃N) were added into a reaction bottle. Next, 5 mL of dimethoxyethane was added into the reaction bottle. After removing moisture and purging nitrogen gas several times, the mixture was heated to 120° C. After reacting for 3 hr, the reaction bottle was cooled to room temperature, and then water was added into the reaction bottle. Next, the result was filtrated. The filter cake was collected and washed with water and hexane, and then dissolved into CH₂Cl₂. The result was extracted three times by CH₂Cl₂ and water as the extraction solvent. Next, an organic phase was separated and dried, and then concentrated by a rotary evaporator. Finally, the result was purified by a sublimation process, obtaining an organic metal compound (I) with a sublimation yield larger than 90%. It should be noted that the chemical bond between the trialkyl silyl group and pyridyl group would be broken when the triethylamine used in the reaction was replaced by an inorganic base (such as Na₂CO₃). Therefore, the use of triethylamine in the reaction can increase the reaction yield and avoid the formation of side products. The synthesis pathway of the above reaction was as follows:

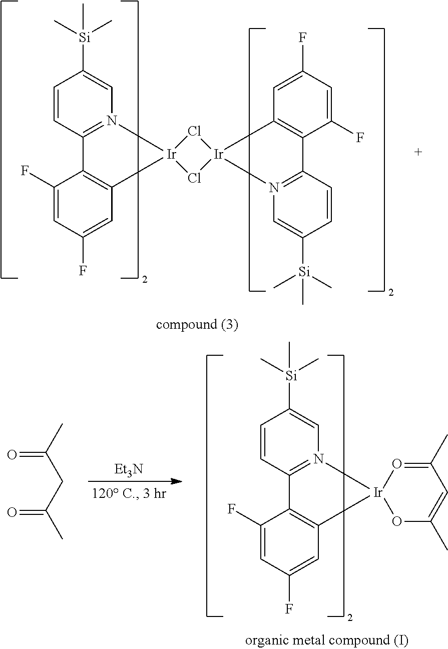

The physical measurement of the organometallic compound (I) is listed below: ¹H NMR (200 MHz, CDCl₃, 294 K): δ 8.74 (s, 2H), 8.19 (d, 2H), 7.84 (d, 2H), 6.32 (ddd, 2H), 5.68 (dd, 2H), 5.28 (s, 1H), 1.81 (s, 6H), 0.33 (s, 18H). Elemental analysis: C₃₃H₃₅F₄IrN₂O₂Si₂: N, 3.43; C, 48.57; H, 4.32. Found: N, 3.39; C, 48.62; H, 4.30.

### Example 2

### Preparation of Organic Metal Compound (II)

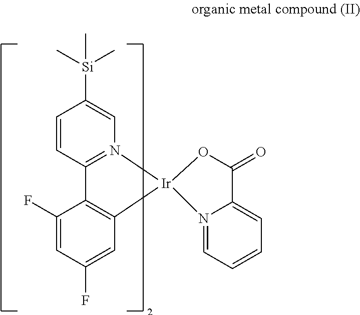

0.5 g (0.33 mmol) of compound (3), 164 mg (1.33 mmol) of picolinic acid, and 0.1 ml (1.33 mmol) of triethylamine (Et₃N) were added into a reaction bottle. Next, 5 mL of dimethoxyethane was added into the reaction bottle. After removing moisture and purging nitrogen gas several times, the mixture was heated to 120° C. After reacting for 3 hr, the reaction bottle was cooled to room temperature, and then water was added into the reaction bottle. Next, the result was filtrated. The filter cake was collected and washed with water and hexane, and then dissolved into CH₂Cl₂. The result was extracted three times by CH₂Cl₂ and water as the extraction solvent. Next, an organic phase was separated and dried, and then concentrated by a rotary evaporator. Finally, the result was purified by a sublimation process, obtaining an organic metal compound (II) with a sublimation yield larger than 90%. It should be noted that the chemical bond between the trialkyl silyl group and pyridyl group would be broken when the triethylamine used in the reaction was replaced by an inorganic base (such as Na₂CO₃). Therefore, the use of triethylamine in the reaction can increase the reaction yield and avoid the formation of side products. The synthesis pathway of the above reaction was as follows:

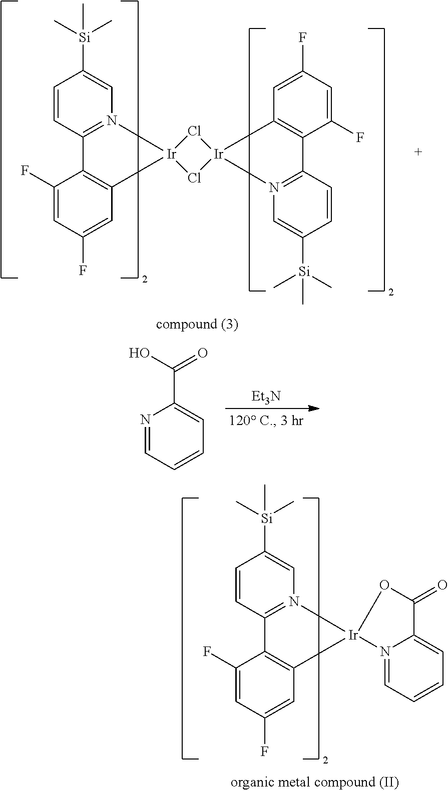

The physical measurement of the organometallic compound (II) is listed below: ¹H NMR (200 MHz, CDCl₃, 294 K): δ 8.77 (s, 1H), 8.34 (d, 1H), 8.24-8.17 (m, 2H), 7.96 (t, 1H), 7.85-7.79 (m, 3H), 7.44 (t, 1H), 7.30 (s, 1H), 6.53-6.33 (m, 2H), 5.82 (dd, 1H), 5.58 (dd, 1H), 0.29 (s, 9H), 0.06 (s, 9H). Elemental analysis: C₃₄H₃₂F₄IrN₃O₂Si₂: N, 5.01; C, 48.67; H, 3.84. Found: N, 5.03; C, 48.70; H, 3.85.

### Example 3

### Preparation of Organic Metal Compound (III)

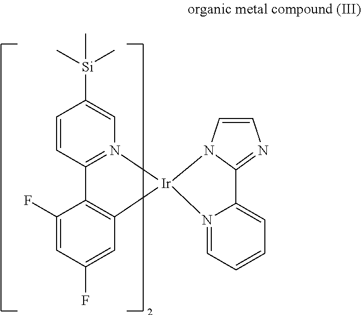

0.5 g (0.33 mmol) of compound (3), 193 mg (1.33 mmol) of 2-(1H-imidazol-2-yl)pyridine, and 0.1 ml (1.33 mmol) of triethylamine (Et₃N) were added into a reaction bottle. Next, 5 mL of dimethoxyethane was added into the reaction bottle. After removing moisture and purging nitrogen gas several times, the mixture was heated to 120° C. After reacting for 3 hr, the reaction bottle was cooled to room temperature, and then water was added into the reaction bottle. Next, the result was filtrated. The filter cake was collected and washed with water and hexane, and then dissolved into CH₂Cl₂. The result was extracted three times by CH₂Cl₂ and water as the extraction solvent. Next, an organic phase was separated and dried, and then concentrated by a rotary evaporator. Finally, the result was purified by a sublimation process, obtaining an organic metal compound (III) with a sublimation yield larger than 90%. It should be noted that the chemical bond between the trialkyl silyl group and pyridyl group would be broken when the triethylamine used in the reaction was replaced by an inorganic base (such as Na₂CO₃). Therefore, the use of triethylamine in the reaction can increase the reaction yield and avoid the formation of side products. The synthesis pathway of the above reaction was as follows:

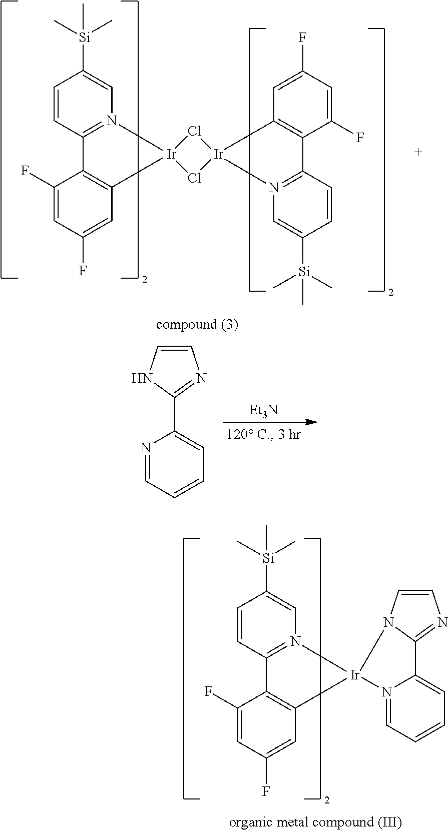

The physical measurement of the organometallic compound (III) is listed below: ¹H NMR (200 MHz, CDCl₃, 294 K): δ 8.20-8.13 (m, 3H), 7.75-7.68 (m, 4H), 7.60 (d, 2H), 7.28 (s, 1H), 6.97 (t, 1H), 6.60 (s, 1H), 6.53-6.38 (m, 2H), 5.84 (dd, 1H), 5.73 (dd, 1H), 0.12 (s, 9H), 0.07 (s, 9H). Elemental analysis: C₃₆H₃₄F₄IrN₅Si₂: N, 8.13; C, 50.21; H, 3.98. Found: N, 8.11; C, 50.16; H, 4.02.

### Example 4

### Preparation of Organic Metal Compound (IV)

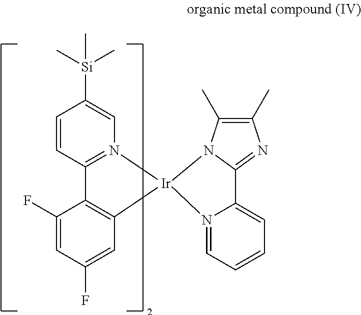

0.5 g (0.33 mmol) of compound (3), 230 mg (1.33 mmol) of 2-(4,5-dimethyl-1H-imidazol-2-yl)pyridine, and 0.1 ml (1.33 mmol) of triethylamine (Et₃N) were added into a reaction bottle. Next, 5 mL of dimethoxyethane was added into the reaction bottle. After removing moisture and purging nitrogen gas several times, the mixture was heated to 120° C. After reacting for 3 hr, the reaction bottle was cooled to room temperature, and then water was added into the reaction bottle. Next, the result was filtrated. The filter cake was collected and washed with water and hexane, and then dissolved into CH₂Cl₂. The result was extracted three times by CH₂Cl₂ and water as the extraction solvent. Next, an organic phase was separated and dried, and then concentrated by a rotary evaporator. Finally, the result was purified by a sublimation process, obtaining an organic metal compound (IV) with a sublimation yield larger than 90%. It should be noted that the chemical bond between the trialkyl silyl group and pyridyl group would be broken when the triethylamine used in the reaction was replaced by an inorganic base (such as Na₂CO₃). Therefore, the use of triethylamine in the reaction can increase the reaction yield and avoid the formation of side products. The synthesis pathway of the above reaction was as follows:

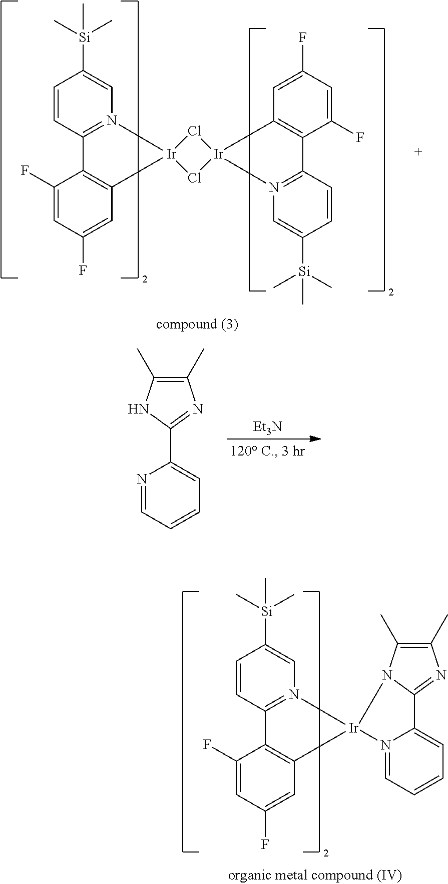

The physical measurement of the organometallic compound (IV) is listed below: ¹H NMR (200 MHz, CDCl₃, 294 K): δ 8.24-8.16 (m, 3H), 7.80-7.71 (m, 4H), 7.62 (d, 1H), 7.50 (s, 1H), 6.99 (s, 1H), 6.55-6.38 (m, 2H), 5.72-5.59 (m, 2H), 2.31 (s, 3H), 1.51 (s, 3H), 0.16 (s, 9H), 0.07 (s, 9H). Elemental analysis: C₃₈H₃₈F₄IrN₅Si₂: N, 7.88; C, 51.33; H, 4.31. Found: N, 7.90; C, 51.30; H, 4.28.

### Example 5

### Preparation of Organic Metal Compound (V)

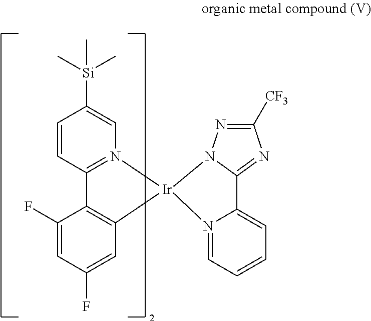

0.5 g (0.33 mmol) of compound (3), 285 mg (1.33 mmol) of 2-[3-(trifluoromethyl)-1H-1,2,4-triazol-5-yl]pyridine, and 0.1 ml (1.33 mmol) of triethylamine (Et₃N) were added into a reaction bottle. Next, 5 mL of dimethoxyethane was added into the reaction bottle. After removing moisture and purging nitrogen gas several times, the mixture was heated to 120° C. After reacting for 3 hr, the reaction bottle was cooled to room temperature, and then water was added into the reaction bottle. Next, the result was filtrated. The filter cake was collected and washed with water and hexane, and then dissolved into CH₂Cl₂. The result was extracted three times by CH₂Cl₂ and water as the extraction solvent. Next, an organic phase was separated and dried, and then concentrated by a rotary evaporator. Finally, the result was purified by a sublimation process, obtaining an organic metal compound (V) with a sublimation yield larger than 90%. It should be noted that the chemical bond between the trialkyl silyl group and pyridyl group would be broken when the triethylamine used in the reaction was replaced by an inorganic base (such as Na₂CO₃). Therefore, the use of triethylamine in the reaction can increase the reaction yield and avoid the formation of side products. The synthesis pathway of the above reaction was as follows:

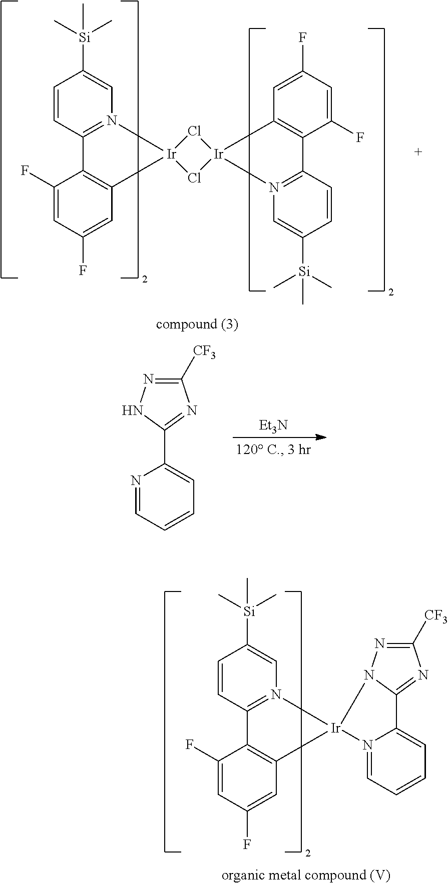

The physical measurement of the organometallic compound (V) is listed below: ¹H NMR (200 MHz, CDCl₃, 294 K): δ 8.32 (d, 1H), 8.25-8.14 (m, 2H), 8.93 (t, 1H), 7.88-7.75 (m, 3H), 7.63 (s, 1H), 7.37 (s, 1H), 7.29-7.23 (m, 1H), 6.56-6.38 (m, 2H), 5.76-5.71 (m, 2H), 0.13 (s, 9H), 0.0 (s, 9H). Elemental analysis: C₃₆H₃₂F₇IrN₆Si₂: N, 9.04; C, 46.49; H, 3.47. Found: N, 9.01; C, 46.48; H, 3.47.

### Example 6

### Preparation of Organic Metal Compound (VI)

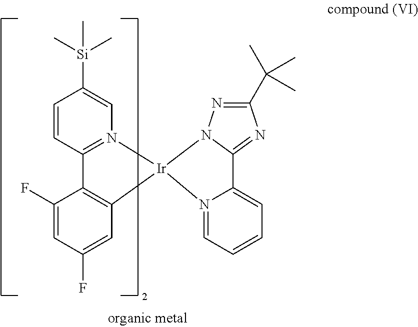

0.5 g (0.33 mmol) of compound (3), 269 mg (1.33 mmol) of 2-[3-(tert-butyl)-1H-1,2,4-triazol-5-yl]pyridine, and 0.1 ml (1.33 mmol) of triethylamine (Et₃N) were added into a reaction bottle. Next, 5 mL of dimethoxyethane was added into the reaction bottle. After removing moisture and purging nitrogen gas several times, the mixture was heated to 120° C. After reacting for 3 hr, the reaction bottle was cooled to room temperature, and then water was added into the reaction bottle. Next, the result was filtrated. The filter cake was collected and washed with water and hexane, and then dissolved into CH₂Cl₂. The result was extracted three times by CH₂Cl₂ and water as the extraction solvent. Next, an organic phase was separated and dried, and then concentrated by a rotary evaporator. Finally, the result was purified by a sublimation process, obtaining an organic metal compound (VI) with a sublimation yield larger than 90%. It should be noted that the chemical bond between the trialkyl silyl group and pyridyl group would be broken when the triethylamine used in the reaction was replaced by an inorganic base (such as Na₂CO₃). Therefore, the use of triethylamine in the reaction can increase the reaction yield and avoid the formation of side products. The synthesis pathway of the above reaction was as follows:

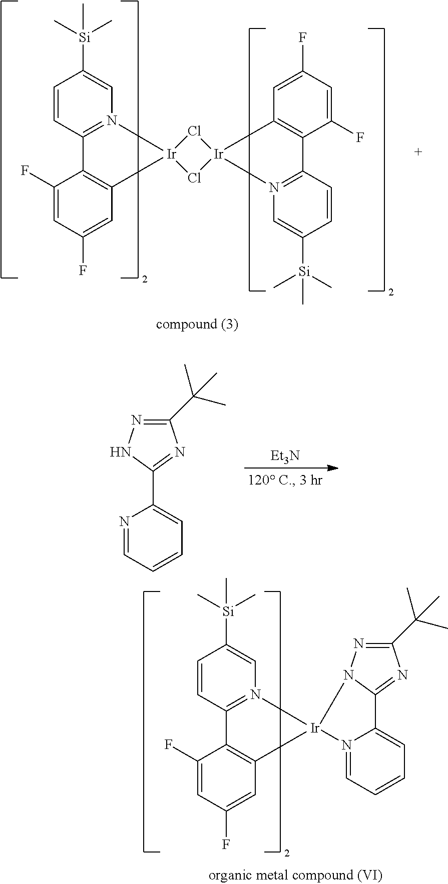

The physical measurement of the organometallic compound (VI) is listed below: ¹H NMR (200 MHz, CDCl₃, 294 K): δ 8.25-8.13 (m, 3H), 7.86-7.74 (m, 5H), 7.39 (s, 1H), 7.15 (s, 1H), 6.54-6.39 (m, 2H), 5.71-5.63 (m, 2H), 1.41 (s, 9H), 0.16 (s, 9H), 0.05 (s, 9H). Elemental analysis: C₃₉H₄₁F₄IrN₆Si₂: N, 9.15; C, 51.02; H, 4.50. Found: N, 9.16; C, 51.04; H, 4.53.

### Example 7

### Preparation of Organic Metal Compound (VII)

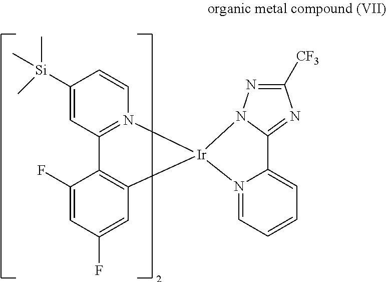

After removing moisture and purging nitrogen gas several times, 5 g (21.11 mmol) of 2,4-dibromopyridine, and 210 mL of ether were added into a reaction bottle. After cooling to −78° C., 3 mL (4.64 mmol) of n-BuLi was slowly added into the reaction bottle. After stirring for 1 hr, 3.2 mL (25.33 mmol) of trimethylchlorosilane was added into the reaction bottle. After returning to room temperature, the result was extracted three times using ethyl acetate (EA) and water as the extraction solvent. An organic phase was separated and dried, and then purified by column chromatography, obtaining compound (4), with a yield larger than 80%. The synthesis pathway of the above reaction was as follows:

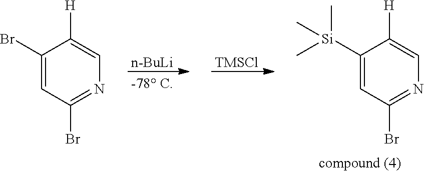

The physical measurement of the compound (4) is listed below: ¹H NMR (200 MHz, CDCl₃, 294 K): δ 8.31 (d, 1H), 7.54 (s, 1H), 7.31 (d, 1H), 0.29 (s, 9H).

Next, 2.6 g (11.35 mmol) of compound (4), 1.97 g (12.5 mmol) of 2,4-difluorophenyl bronic acid, and 1.72 g (12.5 mmol) of potassium carbonate was added into a reaction bottle. Next, 80 mL of dimethoxyethane, 40 mL of water, and a catalyst amount of tetrakis(triphenylphosphine)palladium (Pd(PPh₃)₄) were added into the reaction bottle. After removing moisture and purging nitrogen gas several times, the mixture was heated to reflux. After reacting for 8 hr and then cooling to room temperature, NaHCO₃ (aq) was added into the reaction bottle to adjust the pH value to a weak base condition. The result was extracted three times using ethyl acetate (EA) and water as the extraction solvent. Next, an organic phase was separated and dried, and then purified by column chromatography, obtaining compound (5) with a yield larger than 80%. The synthesis pathway of the above reaction was as follows:

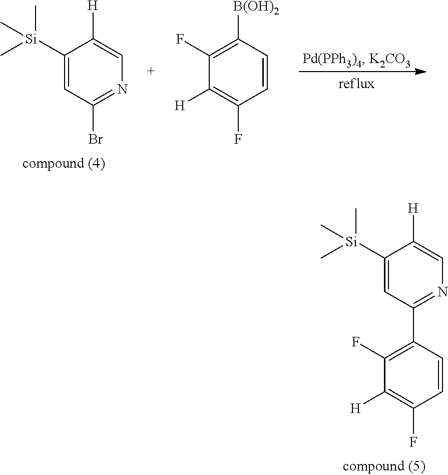 [SMILES: C[Si](C)(C)c1ccnc(Br)c1 ; OB(O)c1ccc(F)cc1F ; C[Si](C)(C)c1ccnc(-c2ccc(F)cc2F)c1]

The physical measurement of the compound (5) is listed below: ¹H NMR (200 MHz, CDCl₃, 294 K): δ 8.66 (d, 1H), 7.94 (q, 1H), 7.81 (d, 1H), 7.35 (d, 1H), 7.05-6.86 (m, 2H), 0.32 (s, 9H). Elemental analysis: C₁₄H₁₅F₂NSi: N, 5.32; C, 63.85; H, 5.74. Found: N, 5.33; C, 63.82; H, 5.73.

Next, 1.7 g (6.6 mmol) of compound (5), and (0.89 g (3 mmol) of IrCl₃ were added into a reaction bottle. Next, 24 mL of dimethoxyethane and 8 mL of water were added into a reaction bottle. After removing moisture and purging nitrogen gas several times, the mixture was heated to 120° C. After reacting for 8 hr, the result was filtrated. The filter cake was collected and washed with water and hexane, and then dried under vacuum, obtaining compound (6). The synthesis pathway of the above reaction was as follows:

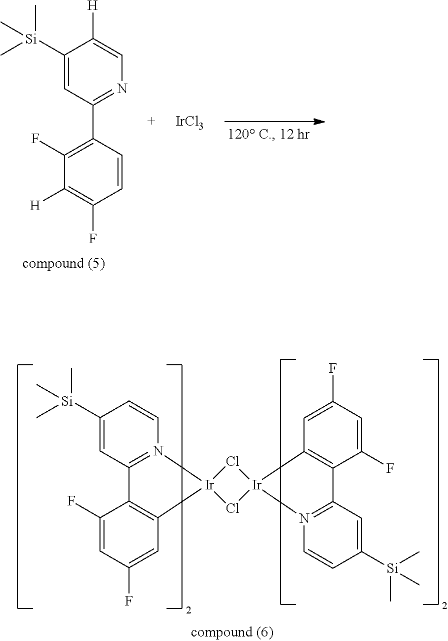

Next, 0.5 g (0.33 mmol) of compound (3), 285 mg (1.33 mmol) of 2-[3-(trifluoromethyl)-1H-1,2,4-triazol-5-yl]pyridine, and 0.1 ml (1.33 mmol) of triethylamine (Et₃N) were added into a reaction bottle. Next, 5 mL of dimethoxyethane was added into the reaction bottle. After removing moisture and purging nitrogen gas several times, the mixture was heated to 120° C. After reacting for 3 hr, the reaction bottle was cooled to room temperature, and then water was added into the reaction bottle. Next, the result was filtrated. The filter cake was collected and washed with water and hexane, and then dissolved into CH₂Cl₂. The result was extracted three times by CH₂Cl₂ and water as the extraction solvent. Next, an organic phase was separated and dried, and then concentrated by a rotary evaporator. Finally, the result was purified by a sublimation process, obtaining an organic metal compound (VII) with a sublimation yield larger than 90%. It should be noted that the chemical bond between the trialkyl silyl group and pyridyl group would be broken when the triethylamine used in the reaction was replaced by an inorganic base (such as Na₂CO₃). Therefore, the use of triethylamine in the reaction can increase the reaction yield and avoid the formation of side products. The synthesis pathway of the above reaction was as follows:

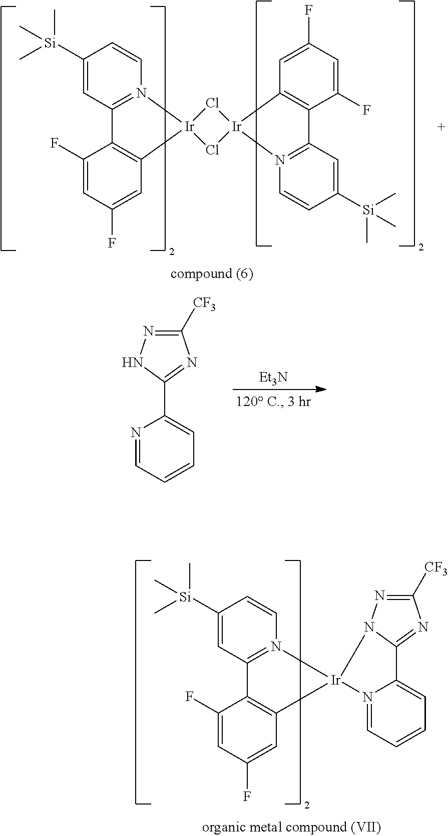

The physical measurement of the organic metal compound (VII) is listed below: ¹H NMR (200 MHz, CDCl₃, 294 K): δ 8.31 (t, 3H), 7.89 (t, 1H), 7.75 (d, 1H), 7.62 (d, 1H), 7.32 (d, 1H), 7.21 (d, 1H), 7.06 (d, 1H), 6.95 (d, 1H), 6.57-6.38 (m, 2H), 5.83-5.66 (m, 2H), 0.32 (s, 18H). Elemental analysis: C₃₆H₃₂F₇IrN₆Si₂: N, 9.04; C, 46.49; H, 3.47. Found: N, 9.07; C, 46.51; H, 3.45.

As disclosed in Examples 1 and 7, the compounds (2) and (5), which have a trialkyl silyl group, can serve as a ligand for bonding with Ir. Further, the compounds (2) and (5) are simple in preparation (through two steps synthesis) with a great yield (more than 80%).

The conventional phosphorescent material FIr(pic) (having a structure represented by

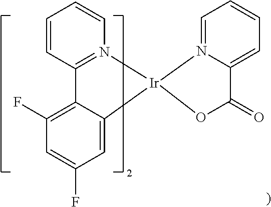

has a sublimation yield of about 50%. On the other hand, since the organic metal compound having Formula (I) of the disclosure has a trialkyl silyl group bonded on the pyridyl group of the ligand bonded with Ir, the organic metal compound having Formula (I) has an improved thermal stability. Therefore, the organic metal compound having Formula (I) of the disclosure is suitable for being purified by a sublimation process (the organic metal compound having Formula (I) of the disclosure has a sublimation yield larger than 90%).

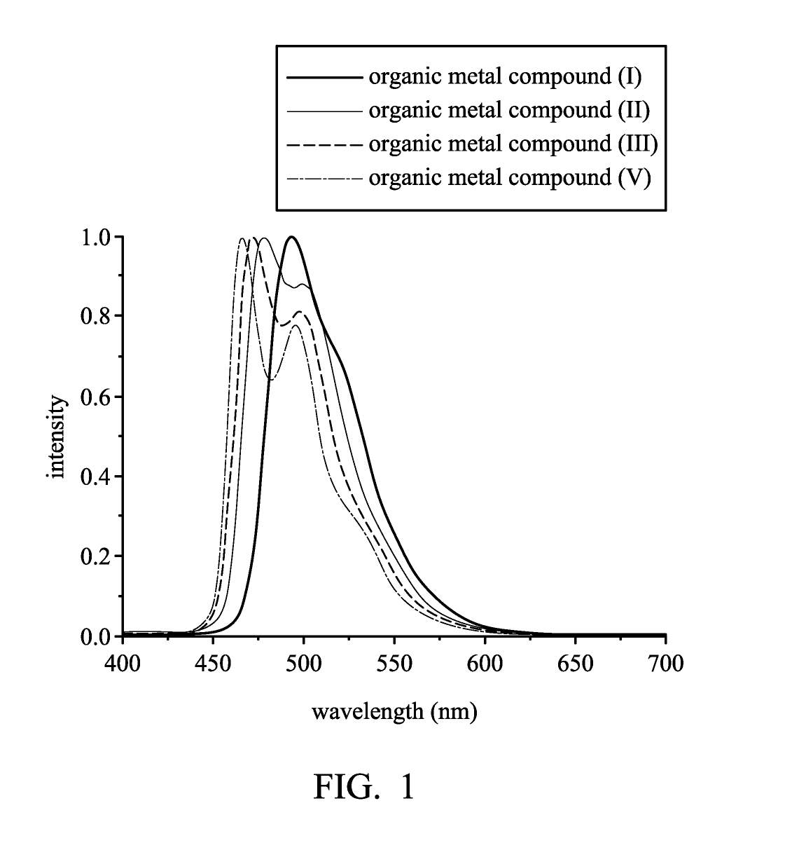

Next, the organic metal compounds (I)-(III) and (V) were dissolved into CH₂Cl₂ respectively obtaining solutions with a concentration of 10⁻⁵ M. Next, the photoluminescence (PL) spectra of the solutions were measured, and the results are shown in FIG. 1 and Table 1.

TABLE 1

| | maximum luminous intensity |
|---|---|
| | peak (Emission λmax ) |
| organic metal compound (I) | 493 nm |
| organic metal compound (II) | 478 nm |
| organic metal compound (III) | 472 nm |
| organic metal compound (V) | 466 nm |

As shown in FIG. 1 and Table 1, the organic metal compound (I) (having an acetylacetone ligand) has a maximum luminous intensity peak of 493 nm (i.e. organic metal compound (I) is a greenish blue phosphorescent material). Further, the organic metal compounds of the disclosure having a strong electron-withdrawing ligand (such as: picolinate ligand, 2-(1H-imidazol-2-yl)pyridine(2-(1H-imidazol-2-yl) pyridine) ligand, or 3-(trifluoromethyl)-5-(pyridine-2-yl)-1,2,4-triazolate ligand) can serve as blue phosphorescent materials. Further, the maximum luminous intensity peak (466 nm) of the organic metal compound (V) can have a 9 nm blue-shift in comparison with the maximum luminous intensity peak (475 nm) of the conventional phosphorescent material FIr(pic).

Organic Light-Emitting Device

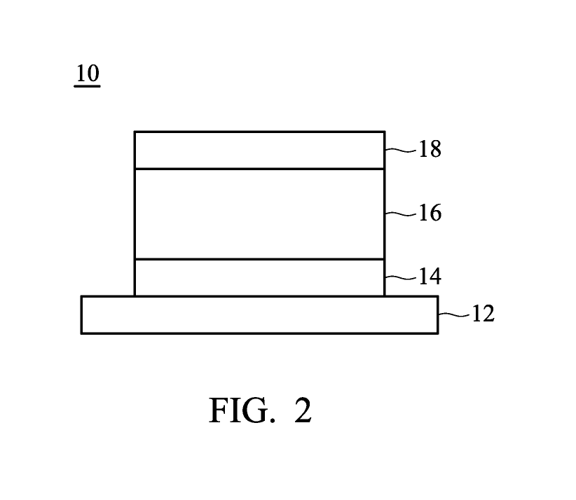

FIG. 2 shows an embodiment of an organic light-emitting device 10. The organic light-emitting device 10 includes a substrate 12, a bottom electrode 14, an organic light-emitting element 16, and a top electrode 18, as shown in FIG. 2. The organic light-emitting device can be a top-emission, bottom-emission, or dual-emission devices. The substrate 12 can be a glass, plastic, or semiconductor substrate. Suitable materials for the bottom and top electrodes can be Ca, Ag, Mg, Al, Li, In, Au, Ni, W, Pt, Cu, indium tin oxide (ITO), indium zinc oxide (IZO), aluminum zinc oxide (AZO), or zinc oxide (ZnO), formed by sputtering, electron beam evaporation, thermal evaporation, or chemical vapor deposition. Furthermore, at least one of the bottom and top electrodes 14 and 18 is transparent. The organic light-emitting element 16 at least includes an emission layer, and can further include a hole injection layer, a hole transport layer, an electron transport layer, and an electron injection layer. In an embodiment of the disclosure, at least one layer of the organic light-emitting element 16 includes the aforementioned organometallic compound. According to embodiments of the disclosure, the organic light-emitting element 16 can emit blue or green light under a bias voltage. According to another embodiment of the disclosure, the organic light-emitting device can be a phosphorescent organic light-emitting device, and the emission layer of the organic light-emitting element can include a host material and a dopant, wherein the dopant can include the aforementioned organic compounds. The dose of the dopant is not limited and can be optionally modified by a person of ordinary skill in the field.

In order to clearly disclose the organic light-emitting devices of the disclosure, the following examples (employing the organic metal compounds of the disclosure) are intended to illustrate the disclosure more fully without limiting their scope, since numerous modifications and variations will be apparent to those skilled in this art.

### Blue Organic Light-Emitting Device

### Example 8

### Organic Light-Emitting Device (1)

A glass substrate with an indium tin oxide (ITO) film with a thickness of 150 nm was provided and then washed with a cleaning agent, acetone, and isopropanol with ultrasonic agitation. After drying with nitrogen flow, the ITO film was subjected to a UV/ozone treatment for 30 min.

Next, TAPC (1,1-bis[4-[N,N′-di(p-tolyl)amino]phenyl]cyclobexane, with thickness of 40 nm), TCTA (4,4′,4′-tri(N-carbazolyl)triphenylamine) doped with the organic metal compound (III) of Example 3 (the ratio between TCTA and the organic metal compound (III) was 100:6, with a thickness of 5 nm), CzDBS (having a structure represented by

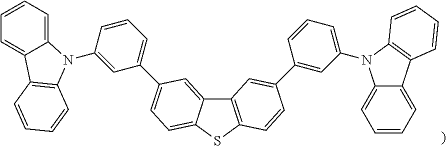 [SMILES: c1cc(-c2ccc3sc4ccc(-c5cccc(-n6c7ccccc7c7ccccc76)c5)cc4c3c2)cc(-n2c3ccccc3c3ccccc32)c1]

doped with the organic metal compound (III) of Example 3 (the ratio between CzDBS and the organic metal compound (III) was 100:6, with a thickness of 5 nm), TmPyPB (1,3,5-tri(p-pyrid-3-yl-phenyl)benzene, with a thickness of 40 nm), LiF (with a thickness of 0.5 nm), and Al (with a thickness of 120 nm) were subsequently formed on the ITO film at 10⁻⁶ torr, obtaining the organic light-emitting device (1). The materials and layers formed therefrom are described in the following: ITO/TAPC/TCTA:organic metal compound (III) (6%)/CzDBS:organic metal compound (III) (6%)/TmPyPB/LiF/Al.

Next, the optical properties of the light-emitting device (1) were measured by a spectra colorimeter PR650 (purchased from Photo Research Inc.) and a luminance meter LS110 (purchased from Konica Minolta). The results are shown in Table 2.

### Example 9

### Organic Light-Emitting Device (2)

A glass substrate with an indium tin oxide (ITO) film with a thickness of 150 nm was provided and then washed with a cleaning agent, acetone, and isopropanol with ultrasonic agitation. After drying with nitrogen flow, the ITO film was subjected to a UV/ozone treatment for 30 min.

Next, TAPC (1,1-bis[4-[N,N′-di(p-tolyl)amino]phenyl]cyclobexane, with thickness of 40 nm), TCTA (4,4′,4′-tri(N-carbazolyl)triphenylamine) doped with the organic metal compound (V) of Example 5 (the ratio between TCTA and the organic metal compound (V) was 100:6, with a thickness of 5 nm), CzDBS (having a structure represented by

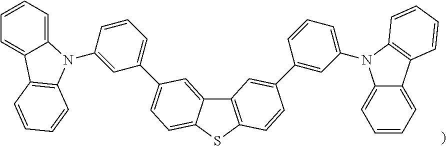 [SMILES: c1cc(-c2ccc3sc4ccc(-c5cccc(-n6c7ccccc7c7ccccc76)c5)cc4c3c2)cc(-n2c3ccccc3c3ccccc32)c1]

doped with the organic metal compound (V) of Example 5 (the ratio between CzDBS and the organic metal compound (V) was 100:6, with a thickness of 5 nm), TmPyPB (1,3,5-tri(p-pyrid-3-yl-phenyl)benzene, with a thickness of 40 nm), LiF (with a thickness of 0.5 nm), and Al (with a thickness of 120 nm) were subsequently formed on the ITO film at 10⁻⁶ torr, obtaining the organic light-emitting device (2). The materials and layers formed therefrom are described in the following: ITO/TAPC/TCTA:organic metal compound (V) (6%)/CzDBS:organic metal compound (V) (6%)/TmPyPB/LiF/Al.

Next, the optical properties of the light-emitting device (2) were measured by a spectra colorimeter PR650 (purchased from Photo Research Inc.) and a luminance meter LS110 (purchased from Konica Minolta). The results are shown in Table 2.

TABLE 2

| | | | maximum | |
|---|---|---|---|---|
| | current | power | luminous | |
| | efficiency | efficiency | intensity peak | |
| | (Cd/A) | (lm/W) | (nm) | C.I.E |
| organic light- | 51.1 | 47.3 | 472 | (0.18, 0.36) |
| emitting device | | | | |
| (1) | | | | |
| organic light- | 30.0 | 26.0 | 466 | (0.16, 0.29) |
| emitting device | | | | |
| (2) | | | | |

### Comparative Example 1

### Organic Light-Emitting Device (3)

A glass substrate with an indium tin oxide (ITO) film with a thickness of 150 nm was provided and then washed with a cleaning agent, acetone, and isopropanol with ultrasonic agitation. After drying with nitrogen flow, the ITO film was subjected to a UV/ozone treatment for 30 min.

Next, TAPC (1,1-bis[4-[N,N′-di(p-tolyl)amino]phenyl]cyclobexane, with thickness of 40 nm), TCTA (4,4′,4′-tri(N-carbazolyl)triphenylamine) doped with FIr(pic) (the ratio between TCTA and FIr(pic) was 100:6, with a thickness of 5 nm), CzDBS (having a structure represented by

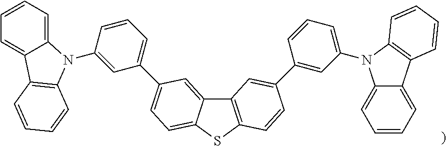 [SMILES: c1cc(-c2ccc3sc4ccc(-c5cccc(-n6c7ccccc7c7ccccc76)c5)cc4c3c2)cc(-n2c3ccccc3c3ccccc32)c1]

doped with FIr(pic) (the ratio between CzDBS and FIr(pic) was 100:6, with a thickness of 5 nm), TmPyPB (1,3,5-tri(p-pyrid-3-yl-phenyl)benzene, with a thickness of 40 nm), Lif (with a thickness of 0.5 nm), and Al (with a thickness of 120 nm) were subsequently formed on the ITO film at 10-6 torr, obtaining the organic light-emitting device (3). The materials and layers formed therefrom are described in the following: ITO/TAPC/TCTA: FIr(pic) (6%)/CzDBS: FIr(pic) (6%)/TmPyPB/LiF/Al.

Next, the optical properties of the light-emitting device (3) were measured by a spectra colorimeter PR650 (purchased from Photo Research Inc.) and a luminance meter LS110 (purchased from Konica Minolta). The light-emitting device (3) has a current efficiency of 36.4 Cd/A, a power efficiency of 30.2 lm/W, a maximum luminous intensity peak of 475 nm, and a C.I.E coordinate of (0.18, 0.38).

In comparison with the organic light-emitting device (3) of the Comparative Example 1, the y value of C.I.E coordinate of the organic light-emitting device (1) of Example 8 has a 0.02 downward-shift. It means that the organic light-emitting device (1) has a more primary blue emission. In addition, the organic light-emitting device (1) has a power efficiency of 47.3 lm/W (measured at a brightness of 1000 Cd/m²), which is about 1.57 times larger than that of the organic light-emitting device (3). Further, the maximum luminous intensity peak (466 nm) of the organic light-emitting device (2) of Example 9 has a 9 nm blue-shift, and the y value of C.I.E coordinate of the organic light-emitting device (2) of Example 9 has a 0.09 downward-shift, in comparison with the organic light-emitting device (3).

The organic light-emitting devices (1) and (3) are subjected to a lifetime test (operated at a brightness of 1000 Cd/m²). The results show that the lifetime of the organic light-emitting device (1) is about 1.53 times larger than that of the organic light-emitting device (3).

### White Organic Light-Emitting Device

### Example 10

### Organic Light-Emitting Device (4)

A glass substrate with an indium tin oxide (ITO) film with a thickness of 150 nm was provided and then washed with a cleaning agent, acetone, and isopropanol with ultrasonic agitation. After drying with nitrogen flow, the ITO film was subjected to a UV/ozone treatment for 30 min.

Next, TAPC (1,1-bis[4-[N,N′-di(p-tolyl)amino]phenyl]cyclobexane, with thickness of 40 nm), TCTA (4,4′,4′-tri(N-carbazolyl)triphenylamine) doped with the organic metal compound (III) of Example 3 (the ratio between TCTA and the organic metal compound (III) was 100:6, with a thickness of 5 nm), PO-01 (having a structure represented by

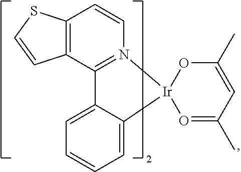

with a thickness of 1 nm), CzDBS (having a structure represented by

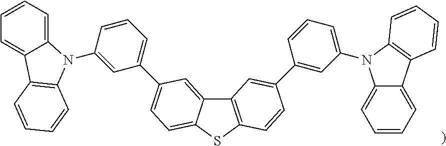 [SMILES: c1cc(-c2ccc3sc4ccc(-c5cccc(-n6c7ccccc7c7ccccc76)c5)cc4c3c2)cc(-n2c3ccccc3c3ccccc32)c1]

doped with the organic metal compound (III) of Example 3 (the ratio between CzDBS and the organic metal compound (III) was 100:6, with a thickness of 5 nm), TmPyPB (1,3,5-tri(p-pyrid-3-yl-phenyl)benzene, with a thickness of 40 nm), LiF (with a thickness of 0.5 nm), and Al (with a thickness of 120 nm) were subsequently formed on the ITO film at 10⁻⁶ torr, obtaining the organic light-emitting device (4). The materials and layers formed therefrom are described in the following: ITO/TAPC/TCTA:organic metal compound (III) (6%)/PO-01/CzDBS: organic metal compound (III) (6%)/TmPyPB/LiF/Al.

Next, the optical properties of the light-emitting device (4) were measured by a spectra colorimeter PR650 (purchased from Photo Research Inc.) and a luminance meter LS110 (purchased from Konica Minolta). The results are shown in Table 3.

### Comparative Example 2

### Organic Light-Emitting Device (5)

A glass substrate with an indium tin oxide (ITO) film with a thickness of 150 nm was provided and then washed with a cleaning agent, acetone, and isopropanol with ultrasonic agitation. After drying with nitrogen flow, the ITO film was subjected to a UV/ozone treatment for 30 min.

Next, TAPC (1,1-bis[4-[N,N′-di(p-tolyl)amino]phenyl]cyclobexane, with thickness of 40 nm), TCTA (4,4′,4′-tri(N-carbazolyl)triphenylamine) doped with FIr(pic) (the ratio between TCTA and FIr(pic) was 100:6, with a thickness of 5 nm), PO-01 (having a structure represented by

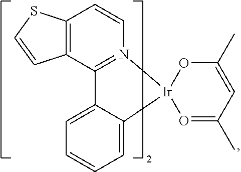

with a thickness of 1 nm), CzDBS (having a structure represented by

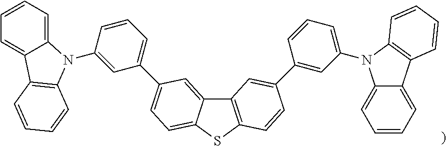 [SMILES: c1cc(-c2ccc3sc4ccc(-c5cccc(-n6c7ccccc7c7ccccc76)c5)cc4c3c2)cc(-n2c3ccccc3c3ccccc32)c1]

doped with FIr(pic) (the ratio between CzDBS and FIr(pic) was 100:6, with a thickness of 5 nm), TmPyPB (1,3,5-tri(p-pyrid-3-yl-phenyl)benzene, with a thickness of 40 nm), LiF (with a thickness of 0.5 nm), and Al (with a thickness of 120 nm) were subsequently formed on the ITO film at 10⁻⁶ torr, obtaining the organic light-emitting device (5). The materials and layers formed therefrom are described in the following: ITO/TAPC/TCTA: FIr(pic) (6%)/PO-01/CzDBS: FIr(pic) (6%)/TmPyPB/LiF/Al.

Next, the optical properties of the light-emitting device (5) were measured by a spectra colorimeter PR650 (purchased from Photo Research Inc.) and a luminance meter LS110 (purchased from Konica Minolta). The results are shown in Table 3.

TABLE 3

| | current | power | |
|---|---|---|---|
| | efficiency | efficiency | |
| | (Cd/A) | (lm/W) | C.I.E |
| organic light- | 74.6 | 68.8 | (0.37, 0.45) |
| emitting device | | | |
| (4) | | | |
| organic light- | | | |
| emitting device | 61.5 | 56.9 | (0.43, 0.47) |
| (5) | | | |

As shown in Table 3, the power efficiency (measured at a brightness of 1000 Cd/m²) of the white organic light-emitting device (4) is about 1.21 times larger than that of the white organic light-emitting device (5).

While the disclosure has been described by way of example and in terms of the preferred embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An organic metal compound, having Formula (I): 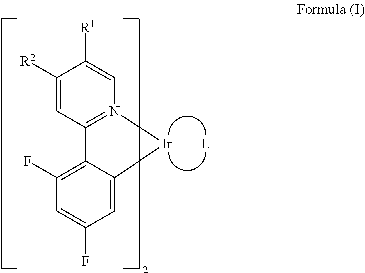
wherein, one of R¹ and R² is hydrogen, and the other one is trialkyl silyl group, and L is acetylacetone ligand, picolinate ligand, 2-(imidazol-2-yl) pyridine ligand, 2-(4,5-dimethyl-imidazol-2-yl)pyridine ligand, 3-(trifluoromethyl)-5-(pyridine-2-yl)-1,2,4-triazolate ligand, or 3-(tert-butyl)-5-(pyridine-2-yl)-1,2,4-triazolate ligand.

2. The organic metal compound as claimed in claim 1, wherein R¹ is hydrogen, and R² is trimethylsilyl group, triethylsilyl group, triphenylsilyl group, tripropylsilyl group, butyldimethylsilyl group, propyldimethylsilyl group, vinyldimethylsilyl group, or t-butyldimethylsilyl group.

3. The organic metal compound as claimed in claim 1, wherein R² is hydrogen, and R¹ is trimethylsilyl group, triethylsilyl group, triphenylsilyl group, tripropylsilyl group, butyldimethylsilyl group, propyldimethylsilyl group, vinyldimethylsilyl group, or t-butyldimethylsilyl group.

4. The organic metal compound as claimed in claim 1, wherein the organic metal compound is 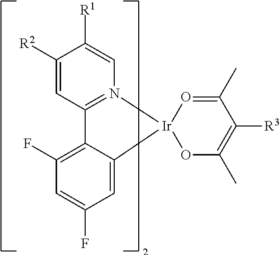
wherein, one of R¹ and R² is hydrogen, and the other one is trialkyl silyl group; and, R³ is hydrogen, C₁₋₁₀ alkyl group, C₅₋₁₀ cycloalkyl group, or C₅₋₁₂ aromatic group.

5. The organic metal compound as claimed in claim 4, wherein R³ is hydrogen, methyl, ethyl, propyl, isopropyl, butyl, isobutyl, tert-butyl, pentyl, hexyl, cyclohexyl, phenyl, biphenyl, or naphthyl.

6. The organic metal compound as claimed in claim 1, wherein the organic metal compound is 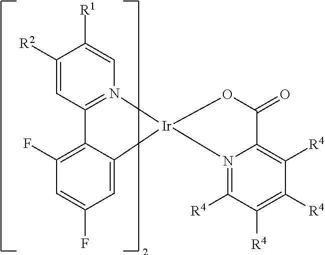
wherein, one of R¹ and R² is hydrogen, and the other one is trialkyl silyl group; and, each R⁴ is independently hydrogen, C₁₋₁₀ alkyl group, C₅₋₁₀ cycloalkyl group, or C₅₋₁₂ aromatic group.

7. The organic metal compound as claimed in claim 6, wherein each R⁴ is independently hydrogen, methyl, ethyl, propyl, isopropyl, butyl, isobutyl, tert-butyl, pentyl, hexyl, cyclohexyl, phenyl, biphenyl, or naphthyl.

8. The organic metal compound as claimed in claim 1, wherein the organic metal compound is 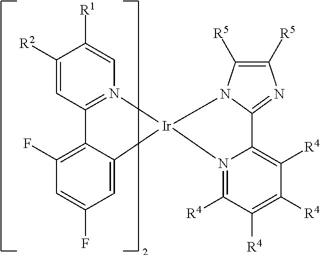
wherein, one of R¹ and R² is hydrogen, and the other one is trialkyl silyl group; each R⁴ is independently hydrogen, C₁₋₁₀ alkyl group, C₅₋₁₀ cycloalkyl group, or C₅₋₁₂ aromatic group; and, R⁵ is hydrogen, or methyl group.

9. The organic metal compound as claimed in claim 8, wherein each R⁴ is independently hydrogen, methyl, ethyl, propyl, isopropyl, butyl, isobutyl, tert-butyl, pentyl, hexyl, cyclohexyl, phenyl, biphenyl, or naphthyl.

10. The organic metal compound as claimed in claim 1, wherein the organic metal compound is 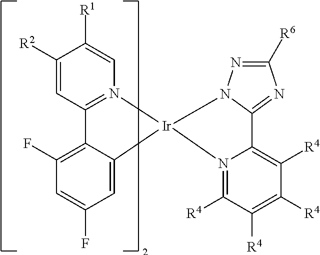
wherein, one of R¹ and R² is hydrogen, and the other one is trialkyl silyl group; each R⁴ is independently hydrogen, C₁₋₁₀ alkyl group, C₅₋₁₀ cycloalkyl group, or C₅₋₁₂ aromatic group; and, R⁶ is fluoroalkyl group, or tert-butyl group.

11. The organic metal compound as claimed in claim 10, wherein each R⁴ is independently hydrogen, methyl, ethyl, propyl, isopropyl, butyl, isobutyl, tert-butyl, pentyl, hexyl, cyclohexyl, phenyl, biphenyl, or naphthyl.

12. An organic light-emitting device, comprising:
a pair of electrodes; and
an organic light-emitting element, disposed between the electrodes, wherein the organic light-emitting element comprises the organic metal compound as claimed in claim 1.

13. A method for preparing the organic metal compound, comprising:
reacting a compound having a structure of Formula (II) with acetyl acetone, picolinic acid, 2-(1H-imidazol-2-yl)pyridine, 2-(4,5-dimethyl-1H-imidazol-2-yl)pyridine, 2-[3-(trifluoromethyl)-1H-1,2,4-triazol-5-yl]pyridine, or 2-[3-(tert-butyl)-1H-1,2,4-triazol-5-yl]pyridine, in the presence of triethylamine, obtaining an organic metal compound having Formula (I) 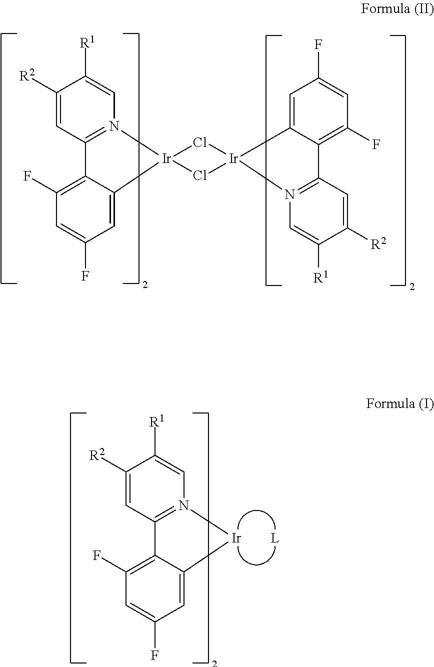
wherein, one of R¹ and R² is hydrogen, and the other one is trialkyl silyl group; and, L is acetylacetone ligand, picolinate ligand, 2-(imidazol-2-yl) pyridine ligand, 2-(4,5-dimethyl-imidazol-2-yl)pyridine ligand, 3-(trifluoromethyl)-5-(pyridine-2-yl)-1,2,4-triazolate ligand, or 3-(tert-butyl)-5-(pyridine-2-yl)-1,2,4-triazolate ligand.
